(19) United States
(12) Patent Application Publication
(10) Pub. No.: US 2008/0144489 A1
(43) Pub. Date: Jun. 19, 2008

(54) NETWORK DEVICE AND COMMUNICATION RECOVERY METHOD THEREOF

(75) Inventors: CHING-I HUANG, Tu-Cheng (TW); WEI-JAN WANG, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/956,346

(22) Filed: Dec. 14, 2007

(30) Foreign Application Priority Data
Dec. 15, 2006 (CN) 200610157537.4

(51) Int. Cl. G01R 31/08; H04L 12/66

(52) U.S. Cl. 370/216; 370/401

(57) ABSTRACT

A network device (20) includes more than an active card (201) and a standby card (200). The active card is used for establishing telephony connection between a first terminal device (10) and a second terminal device (20) via a media gateway control device, and sending communication data between the first terminal device and the media gateway control device. The standby card is used for reestablishing telephony connection between the first terminal device and the second terminal device via a redundancy command and a number of connections of the active card in response to a fault on the active card.

### BACKGROUND OF THE INVENTION

1. Field of the Invention

The invention relates to network devices, and particularly to a VOIP gateway and communication recovery method thereof.

2. Description of Related Art

Voice over IP (VoIP) phones have rapidly emerged as a viable alternative to traditional circuit switched telephony. A VoIP gateway is an important part in the VOIP telephone system for converting telephony traffic into IP packets for transmission over a data network and establishing connection among subscriber terminal devices through a media gateway control device. Stability of VoIP gateways affects the communication among subscriber terminal devices. When a VOIP gateway is down, communication among subscribers is interrupted.

### SUMMARY OF THE INVENTION

An exemplary embodiment of the invention provides a network device for communication recovery. The network device includes more than an active card and a standby card. The active card is used for establishing telephony connection between a first terminal device and a second terminal device via a media gateway control device, and sending communication data between the first terminal device and the media gateway control device. The standby card is used for reestablishing telephony connection between the first terminal device and the second terminal device via a redundancy command and a number of connections of the active card in response to a fault on the active card. A method for communication recovery is also provided.

Other advantages and novel features of the present invention will become more apparent from the following detailed description of preferred embodiment when taken in conjunction with the accompanying drawings, in which:

### BRIEF DESCRIPTION OF THE DRAWINGS

FIG. 1 is a working environment associated with a first network device in accordance with an exemplary embodiment of the invention;

FIG. 2 shows a block diagram of the first network device of FIG. 1;

FIG. 3 shows a block diagram of the first network device in accordance with another exemplary embodiment of the invention;

FIG. 4 shows a flow chart of a method for communication recovery in accordance with a further exemplary embodiment of the invention; and

FIG. 5 shows a flow chart of a method for communication recovery in accordance with a still further exemplary embodiment of the invention.

### DETAILED DESCRIPTION OF THE INVENTION

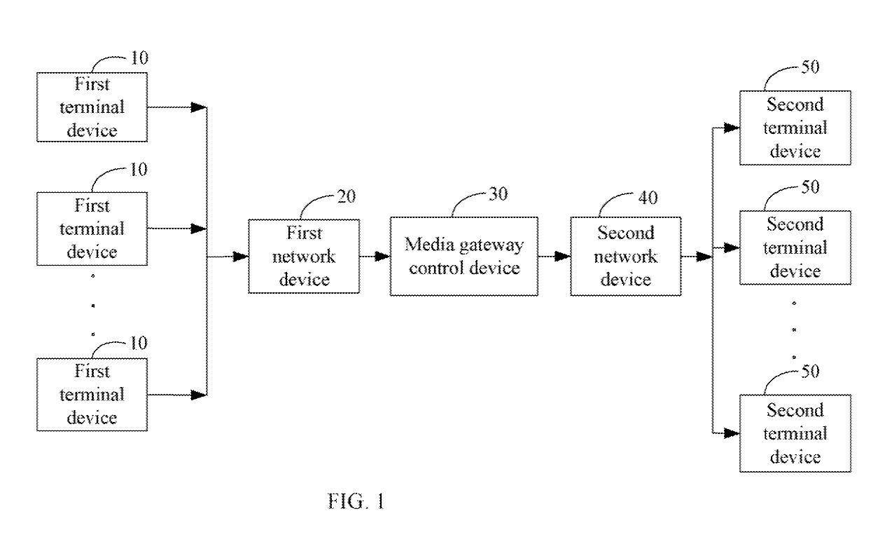

FIG. 1 is a working environment of a first network device 20 in accordance with an exemplary embodiment. In the exemplary embodiment, a first terminal device 10 is connected to a second terminal device 50 through the first network device 20, a media gateway control device 30, and a second network device 40. The first network device 20 is connected to the first terminal device 10 and the media gateway control device 30, the second network device 40 is connected to the media gateway control device 30 and the second terminal device 50. In the exemplary embodiment, the first network device 20 and the second network device 40 may include VOIP gateways. In the exemplary embodiment, the first terminal device 10 and the second terminal device 50 may be telephones. In the exemplary embodiment, the first network device 20 is connected to a plurality of the first terminal devices 10, the second network device 40 is connected to a plurality of the second terminal devices 50, and each of the first terminal devices 10 can connect to a plurality of the second terminal devices 50 at the same time.

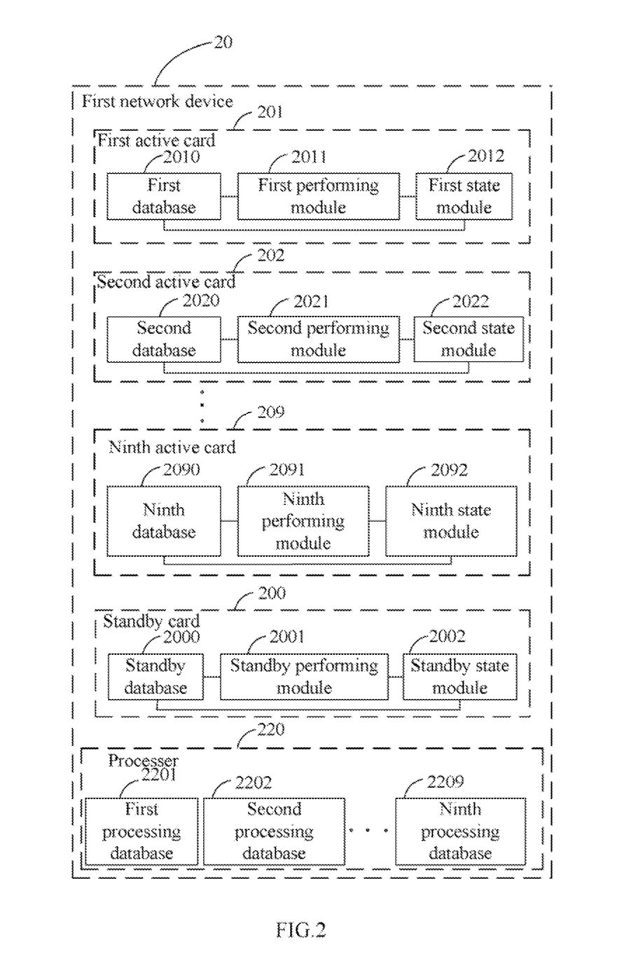

FIG. 2 is a block diagram of the first network device 20 of FIG. 1 in accordance with the exemplary embodiment of the invention. The first network device 20 may include an N+1 redundancy structure or 1+1 redundancy structure. In the exemplary embodiment, the first network device 20 includes an N+1 redundancy structure, in the exemplary embodiment, the N is 9, and the first network device 20 includes a processor 220, a standby card 200, a first active card 201, and a plurality of second active cards 202-209. In another exemplary embodiment, the N may be any number. Each active card serves as a VOIP gateway. In the exemplary embodiment, the first active card 201, and the plurality of second active cards 202-209 are connected to one of the first terminal devices 10 respectively, and all are connected to the media gateway control device 30 and the processor 220. The standby card 200 is connected to each first terminal device 10, the first active card 201, and the plurality of second active cards 202-209, the media gateway control device 30, and the processor 220.

In the exemplary embodiment, the first active card 201, the second active cards 202-209 respectively correspond to the plurality of first terminal devices 10. In the exemplary embodiment, each active card serves one first terminal device 10. Specifically, each of the first active card 201 and the second active cards 202-209 are used for establishing a telephony connection between the corresponding first terminal devices 10 and the second terminal devices 50 via the media gateway control device 30. In the exemplary embodiment, the first active card 201, and the second active cards 202-209 have a same working model. The standby card 200 is also a VOIP gateway for reestablishing the telephony connection between the first terminal devices 10 and the terminal devices 50 in response to any faults on the first active card 201 and/or the second active cards 202-209. The processor 220 can distinguish whether a card is one of the active cards or the standby card 200 by identifying a status indicator associated with the card. The status indicator indicates if a detected card is an “active” card or the standby card. Broadly speaking, data in an active card of a network device (such as a first network device 20 or 40) necessary for reconstruction of a telephony connection between two terminal devices is redundantly backed up in a database. The database may be located in any location (such as in the processor 220 or the standby card 200) external to the active card, whereby when any error or fault occurs on the active card, the standby card 200 can reconstruct a telephony connection associated with the faulty active card utilizing the backup data. Each active card detects communication states of a telephony connection associated with the active card and a corresponding terminal device and can transmit all the data necessary for reconstruction of the telephony connection to the database in response to any change in communication state. The standby card can reconstruct a telephony connection in response to a detected fault on an active card. Faults may be detected by a standby card or a processor, such as the processor 220.

The processor 220 is connected to and detects faults with the first active card 201, and the plurality of second active cards 202-209, and sends a redundancy command to the standby card 200 when one or more of the first active card 201, and the plurality of second active cards 202-209 have a fault or faults. The processor 220 includes a central processing unit (CPU) in the first network device 20. The processor 220 includes a first processing database 2201, and a plurality of second processing databases 2202-2209, each processing database is corresponding to each active card. For example, the first processing database 2201 is connected to the first active card 201, and the first processing database 2201 is used for storing communication data sent by the active card 201. The function of each of the plurality of second processing databases 2202-2209 is the same as the function of the first processing module 2201, i.e. storing communication data sent by the corresponding active card thereof. For simplicity, the function of the plurality of second processing databases 2202-2209 is not described here in detail.

In the exemplary embodiment, each of the first active card 201, and the plurality of second active cards 202-209 includes a database, a performing module, and a state module. In the exemplary embodiment, the first active card 201 includes a first database 2010, a first performing module 2011, and a first state module 2012, the second active cards 202-209 each include a second database 2020-2090, a second performing module 2021-2091, and a second state module 2022-2092 respectively.

The first state module is connected to one of the first terminal devices 10 and the media gateway control module 30, and is used for recording a communication state between the first terminal device 10 and the media gateway control device 30. In the exemplary embodiment, the communication state includes an idle state, a dialing state, a number collecting state, and a call state. A number “0” represents the idle state, a number “1” represents the dialing state, a number “2” represents the number collecting state, and a number “3” represents the call state. In another exemplary embodiment, the communication states may be represented by different arrangement of numbers, letters, or symbols.

The first performing module 2011 is connected to the first terminal device 10, the media gateway control device 30, the processor 220, and the first state module 2012, and is used for establishing telephony connection between the first terminal device 10 and the second terminal device 50 based on the communication state recorded by the first state module 2012.

The first database 2010 is connected to the first state module 2012 and the first performing module 2011, and is used for storing communication data between the first active card 201 and the media gateway control device 30. In the exemplary embodiment, the communication data between the first active card 201 and the media gateway control device 30 includes a plurality of dominant protocol commands, a call agent address, a register state, and a current communication state. In the exemplary embodiment, each dominant protocol command includes a Create Connection (CRCX) command and a Notification Request (RQNT) command pursuant to Media Gateway Control Protocol (MGCP), but is not limited thereto. The communication recovery method may utilize dominant protocol commands conforming to Media Gateway Controller (MEGACO), Session Initiation Protocol (SIP), or others. The CRCX includes a CRCX command line parameter, a connection mode parameter, a call identifier parameter, a number of connections parameter, a local connection option parameter, and a session description protocol parameter. In the exemplary embodiment, the current communication state is a state between the first terminal device 10 and the media gateway control device 30, and may be stored in a state module, such as the first state module 2012. In the exemplary embodiment, the first performing module 2011 is further used for sending the communication data of the first database 2010 and the communication state stored in the state module 2012 to the processor 220 for storage.

The function and the structure of the components in the plurality of second active cards 202-209 are the same as the function and structure of the first active card 201. For simplicity, the function and the structure of the components in the plurality of second active cards 202-209 are not described here in detail.

In the exemplary embodiment, if the processor 220 detects the first active card 201 has errors or faults, it sends a redundancy command, the communication data sent by the first performing module 2011, and the communication states sent by the first state module 2012 to the standby card 200 in response to the detected errors or faults.

In the exemplary embodiment, if the processor 220 detects there is a fault in any of the plurality of second active cards 202-209, it sends a redundancy command, the communication data sent by the second performing modules 2021-2091 and the communication state sent by the second state modules 2022-2092 of the corresponding faulty second active card or cards 202-209, to the standby card 200.

In the exemplary embodiment, the standby card 200 includes a standby database 2000, a standby performing module 2001, and a standby state module 2002.

The standby database 2000 is connected to the processor 220, and stores the communication data sent by the processor 220.

The performing module 2001 is connected to the first terminal devices 10, the media gateway control device 30, the processor 220, and the standby database 2000, and receives the redundancy command sent by the processor 220, and reestablishes telephony with a same number of connections between the corresponding first terminal devices 10 and second terminal devices 50 as the faulty active card.

In the exemplary embodiment, the standby performing module 2001 determines the number of connections of the faulty active card by querying the number of connections parameter of the CRCX of the dominant protocol command stored in the standby database 2000. In the exemplary embodiment, the number of connections parameter may be represented by different numbers, symbols or letters. In the exemplary embodiment, a number “0” represents that the faulty active card is detecting the status of the first terminal device 10 corresponding to the faulty active card. A number “1” represents that the faulty active card has established one connection, for example, between the first terminal device 10 corresponding to the faulty active card and a second terminal 50 via a CRCX command. A number “N” represents that the faulty active card has established a plurality of connections, for example, between the first terminal device 10 corresponding to the faulty active card and a plurality of second terminal devices 50 via a plurality of CRCX commands, each CRCX command corresponds to a connection between one of the first terminal devices 10 one of the second terminal devices 50.

When the standby performing module 2001 determines that the number of connections is not 0, for example, the number of connections is N, the standby performing module 2001 generates a new CRCX command, and subtracts 1 from the number of connections after generating the new CRCX command. In the exemplary embodiment, the standby performing module 2001 copies all parameters of the CRCX command stored in the standby database 2000 for generating the new CRCX command, and processes the new CRCX command.

In the exemplary embodiment, the standby performing module 2001 processes the new CRCX command as the CRCX command sent by the media gateway control device 30 to establish connection between the first terminal device 10 corresponding to the faulty active card and the second terminal device 50. When the standby performing module 2001 determines that the number of connections is 0, the standby performing module 2001 generates a new RQNT command. In the exemplary embodiment, the standby performing module 2001 copies all parameters of the RQNT command stored in the standby database 2000 for generating the new RQNT command, and processes the new RQNT command. In the exemplary embodiment, the standby performing module 2001 processes the new RQNT command as the RQNT command sent by the media gateway control device 30, detects the status of the first terminal device 10 corresponding to the faulty active card, and sends the result of the detecting to the media gateway control device 30.

The standby state module 2002 is connected to the standby database 2000, the standby performing module 2001, the first terminal device 10, and the media gateway control device 30, and is used for recording the communication state between the first terminal device 10 and the media gateway control device 30. In the exemplary embodiment, after the standby performing module 2001 receives the redundancy command, the standby state module 2002 records the communication state between the first terminal device 10 and the media gateway control device 30 sent by the processor 220. The standby performing module 2001 then reestablishes connections according to the communication states recorded in the standby state module 2002.

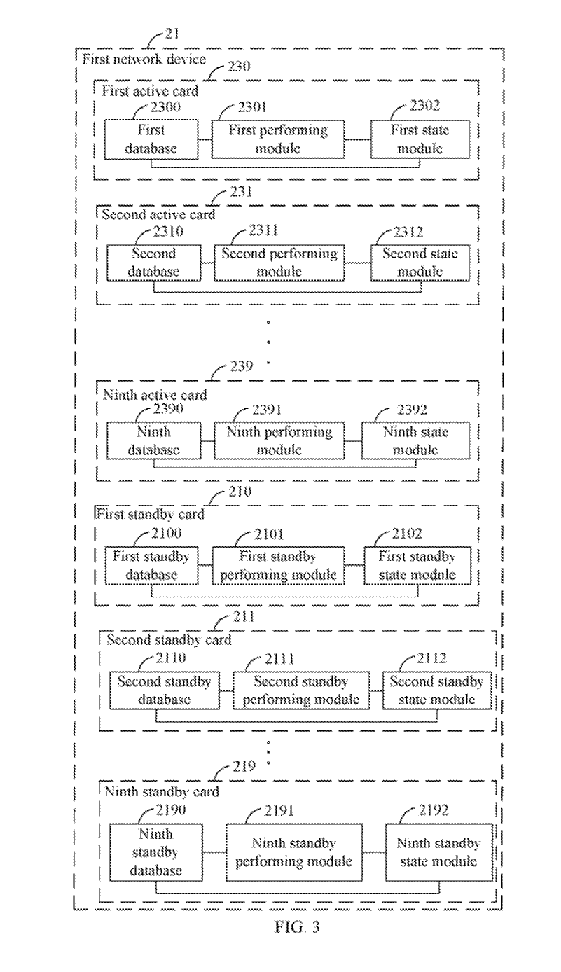

FIG. 3 shows a block diagram of a first network device 21 of another exemplary embodiment. In the exemplary embodiment, the network device 21 may comprise a 1+1 redundancy structure. The first network device 21 includes a first active card 230, and a plurality of second active cards 231-239, and a first standby card 210, and a plurality of second standby cards 211-219. In the exemplary embodiment, each active card corresponds to each standby card, for example, the first active card 230 corresponds to the first standby card 210, the ninth active card 239 corresponds to the ninth standby card 219. Each standby card may serve as a backup of the corresponding active card thereof. The first active card 230 and the first standby card 210 are connected to one first terminal device 10 and the media gateway control device 30, and the first active card 230 is connected to the first standby card 210. The first active card 230, and the plurality of second active cards 231-239 respectively correspond to one first terminal device 10, for example, each active card servers one first terminal device 10.

The first active card 230 includes a first database 2300, a first performing module 2301, and a first state module 2302.

The first state module 2302 is connected to the first terminal device 10 and the media gateway control device 30, and is used for recording the communication state between the first terminal device 10 and the media gateway control device 30. In the exemplary embodiment, the communication state includes the idle state, the dialing state, the number collecting state, and the call state. The number “0” represents the idle state, the number “1” represents the dialing state, the number “2” represents the number collecting state, and the number “3” represents the call state. In another exemplary embodiment, a communication state may be represented by another number or letter.

The first performing module 2301 is connected to the first terminal device 10, the media gateway control device 30, and the first state module 2302, and is used for reestablishing connection between the first terminal device 10 and the second terminal device 50 based on the communication state recorded by the first state module 2302.

The first database 2300 is connected to the first state module 2302 and the first performing module 2301, and is used for storing communication data between the first terminal device 10 and the media gateway control device 30. In the exemplary embodiment, the communication data between the first terminal device 10 and the media gateway control device 30 includes a plurality of dominant protocol commands, a call agent address, a register state, and a current communication state which may be recorded in a state machine, such as the first state module 2302. In the exemplary embodiment, each dominant protocol command includes a Create Connection (CRCX) command and a Notification Request (RQNT) command, the CRCX includes a CRCX command line parameter, a connection mode parameter, a call identifier parameter, a number of connections parameter, a local connection option parameter, and a session description protocol parameter. In the exemplary embodiment, the current communication state is a state between the first terminal device 10 and the media gateway control device 30, and may be stored in the first state module 2302.

The function and the structure of the plurality of second active cards 231-239 may be the same as the function and the structure of the first active card 230. For simplicity, the function and the structure of the plurality of second active cards 231-239 are not described here in detail.

In the exemplary embodiment, the first performing module 2301 is further used for sending the communication data stored in the first database 2300 and the communication state stored in the first state module 2302 to the first standby card 210.

In the exemplary embodiment, after the first standby card 210 detects that the first active card 230 has errors or faults, the first standby card 210 generates a redundancy command automatically, and reestablishes connection between the first terminal device 10 and the media gateway control device 30. The first standby card 210 includes a first standby database 2100, a first standby performing card 2101, and a first standby state module 2102.

The first standby database 2100 is connected to the first performing module 2301, and is used for storing the communication data sent by the first performing module 2301.

The first standby state module 2102 is connected to the first standby database 2100, the first terminal device 10, and the media gateway control device 30, and is used for recording the communication state between the first terminal device 10 and the media gateway control device 30. In the exemplary embodiment, after the first standby card 210 detects that the first active card 230 is faulty, the first standby state module 2102 starts to record the communication state between the first terminal device 10 and the media gateway control device 30.

The first standby performing module 2101 is connected to the first terminal 10, the media gateway control device 30, the first standby database 2100, and the first standby state module 2102, is used for reestablishing connection between the first terminal device 10 and the media gateway control device 30 based on the number of connections of the first active card 230 if the first active card 230 is faulty. In the exemplary embodiment, the first standby performing module 2101 determines the number of connections of the first active card 230 by querying the number of connections parameter of the CRCX of the dominant protocol command stored in the first standby database 2100. In the exemplary embodiment, the number of connections parameter may be represented by different numbers or letters. In the exemplary embodiment, a number “0” represents that the first active card 230 is detecting the first terminal device 10, a number “1” represents that there is one connection between the first active card 230 and the media gateway control device 30, for example, the first terminal device 10 corresponding to the first active card 230 has established connection with the second terminal 50 via a CRCX command. A number “N” represents that there are a plurality of connections between the first active card 230 and the media gateway control device 30. For example, the first terminal device 10 corresponding to the first active card 230 has established connection with a plurality of second terminal devices 50 via a plurality of CRCX commands, where each CRCX command corresponds to the first terminal device 10 establishing connection with each second terminal device 50.

When the first standby performing module 2101 determines that the number of connections is not 0, for example, the number of connections is N, the first standby performing module 2101 generates a new CRCX command, and subtracts 1 from the number of connections after generating the new CRCX command. In the exemplary embodiment, the first standby performing module 2101 copies all parameters of CRCX command stored in the first standby database 2100, for generating the new CRCX command, and processes the CRCX command.

When the first standby performing module 2101 determines that the number of connections is 0, the first standby performing module 2101 generates a new RQNT command. In the exemplary embodiment, the first standby performing module 2101 copies all parameters of the RQNT command stored in the first standby database 2100 for generating a new RQNT command, and processes the new RQNT command. In the exemplary embodiment, the first standby performing module 2101 utilizes the new RQNT command as the RQNT command sent by the media gateway control device 30, detects the status of the first terminal device 10 corresponding to the faulty active card, and sends the result of the detecting to the media gateway control device 30. The status of the first terminal device 10 may includes on-hook, off-hook, or hook flash state.

The function and the structure of the plurality of second standby cards 211-219 may be the same as the function and the structure of the first standby card 210. For the simplicity, the function and the structure of the second standby cards 211-219 are not described here in detail.

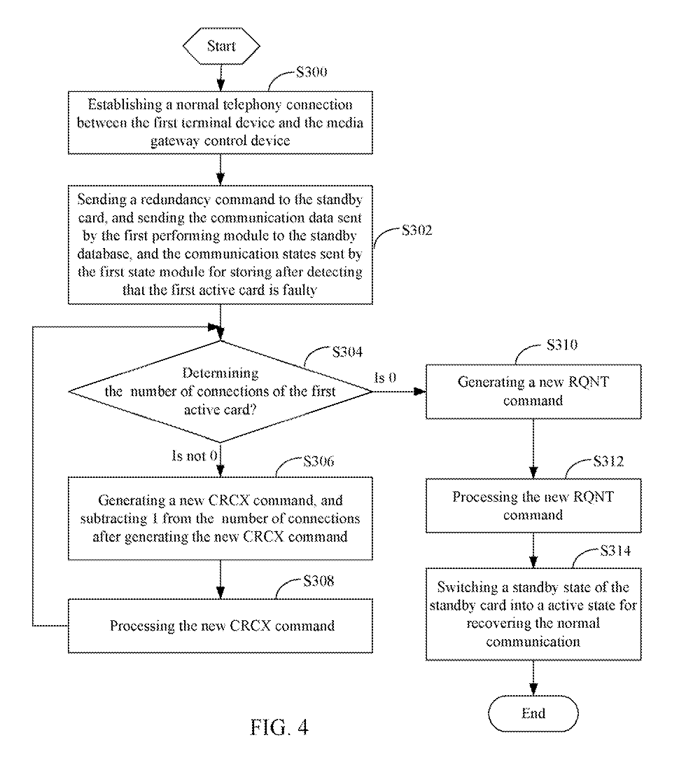

FIG. 4 shows a flow chart of a method for communication recovery in accordance with an exemplary embodiment of the invention. In the exemplary embodiment, the first network device 20 performs a same communication recovery method for the first active card 201, and the plurality of second active cards 202-209, therefore, taking the first active card 201 for example.

In step S300, the first active card 201 establishes a normal telephony connection between the first terminal device 10 and the media gateway control device 30. In the exemplary embodiment, the first performing module 2011 establishes a communication connection between the first terminal device 10 corresponding to the first active card 201 and the second terminal device 50 via the media gateway control device 30, the first database 2010 stores communication data between the first active card 201 and the media gateway control device 30, the communication data includes a plurality of dominant protocol commands, a call agent address, a register state, and a current communication state, the first performing module 2011 sends the communication data stored in the first database 2010 to the processor 220.

In the exemplary embodiment, each dominant protocol command includes a Create Connection (CRCX) command and a Notification Request (RQNT) command, the CRCX includes a CRCX command line parameter, a connection mode parameter, a call identifier parameter, a number of connections parameter, a local connection option parameter, and a session description protocol parameter. In the exemplary embodiment, the current communication state is a state between the first terminal device 10 corresponding to the first active card 201 and the media gateway control device 30, and may be stored in the first state module 2012. In the exemplary embodiment, a number “0” represents the idle state, a number “1” represents the dialing state, a number “2” represents the number collecting state, and a number “3” represents the call state. In another exemplary embodiment, the communication state may be represented by different arrangement of numbers or letters.

In step S302, the processor 220 sends a redundancy command to the standby card 200 and the communication data sent by the first performing module 2011 to the standby database 2000, and sends the communication states from the first state module 2012 to the standby state module 2002 for storage after detecting that the first active card 201 is faulty.

In step S304, the standby performing module 2001 determines the number of connections of the first active card 201. In the exemplary embodiment, after the standby card 200 receives the redundancy command sent by the processor 220, the standby performing module 2001 determines the number of connections of the first active card 201 by querying the number of connections parameter of the CRCX command of the dominant protocol command stored in the standby database 2000. In the exemplary embodiment, a number “0” represents that the faulty active card is detecting the first terminal device 10 corresponding to the first active card 201, a number “1” represents that there is one connection between the faulty active card and the media gateway control device 30, for example, the first terminal device 10 corresponding to the faulty active card has established communication connection with a second terminal 50 via a CRCX command. A number “N” represents that there are N connections between the faulty active card and the media gateway control device 30, for example, the first terminal device 10 corresponding to the faulty active card has established communication connection with N second terminal device 50 via N CRCX commands, each CRCX command corresponds to the first terminal device 10 establishing communication connection with each second terminal device 50.

When the standby performing module 2001 determines that the number of connections is not 0, for example, the number of connections is N, in step S306, the standby performing module 2001 generates a new CRCX command, and subtracts 1 from the number of connections after generating the new CRCX command. In the exemplary embodiment, the standby performing module 2001 copies all parameters of CRCX command stored in the standby database 2000 for generating the new CRCX command for getting ready for reestablishing connection between the first terminal device 10 corresponding to the first active card 201 and the media gateway control device 30.

In step S308, the standby performing module 2001 processes the new CRCX command. In the exemplary embodiment, the standby performing module 2001 utilizes the new CRCX command as a CRCX command sent by the media gateway control device 30 for communicating with the media gateway control device 30, and turns to step S304.

When the standby performing module 2001 determines that the number of connections is 0, in step S310, the standby performing module 2001 generates a new RQNT command. In the exemplary embodiment, the standby performing module 2001 copies all parameter of the RQNT command stored in the standby database 2000 for generating a new RQNT command.

In step S312, the standby performing module 2001 processes the new RQNT command. In the exemplary embodiment, the first standby performing module 2101 utilizes the new RQNT command as the RQNT command sent by the media gateway control device 30, detects the status of the first terminal device 10 corresponding to the faulty active card, and sends the results of the detecting to the media gateway control device 30.

In step S314, the standby card 200 switches a standby state of the standby card 200 into a active state for recovering the normal communication.

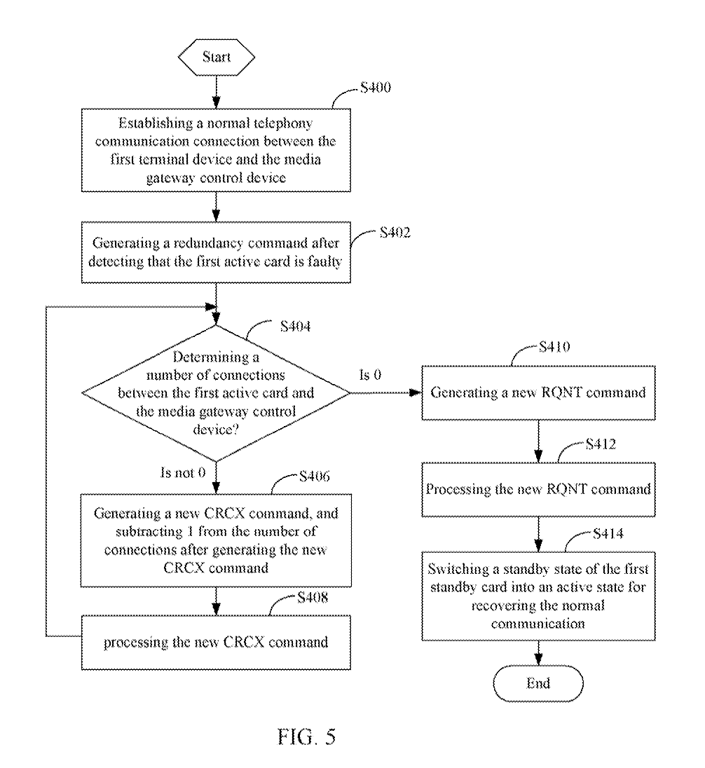

FIG. 5 shows a flow chart of a method for communication recovery in accordance with another still exemplary embodiment of the invention. In step S400, the first active card 230 establishes a normal communication connection between the first terminal device 10 and the media gateway control device 30. In the exemplary embodiment, the first performing module 2301 establishes a communication connection between the first terminal 10 and the second terminal device 50 via the media gateway control device 30, the first database 2300 stores a plurality of current communication data between the first terminal device 10 and the media gateway control device 30, the plurality of current communication data includes a plurality of dominant protocol commands, a call agent address, a register state, and a current communication state. The first performing module 2301 sends the plurality of current communication data stored in the first database 2300 to the first standby database 2100 for storage. In the exemplary embodiment, each dominant protocol command includes a Create Connection (CRCX) command and a Notification Request (RQNT) command, and the CRCX includes a CRCX command line parameter, a connection mode parameter, a call identifier parameter, a number of connections parameter, a local connection option parameter, and a session description protocol parameter. In the exemplary embodiment, the current communication state is a state between the first terminal device 10 and the media gateway control device 30, and stores in the first state module 2302. In the exemplary embodiment, a number “0” represents the idle state, a number “1” represents the dialing state, a number “2” represents the number collecting state, and a number “3” represents the call state. In another exemplary embodiment, a communication state may be represented by another number or letter.

In step S402, the first standby card 210 generates a redundancy command after detecting that the first active card 230 is faulty.

In step S404, the first standby card 2101 determines a number of connections between the first active card 230 and the media gateway control device 30. In the exemplary embodiment, the first performing module 2101 begins to determine the number of connections between the first active card 230 and the media gateway control device 30 after the first standby card 2101 generates the redundancy command. In the exemplary embodiment, the first performing module 2101 determines the number of connections between the first active card 230 and the media gateway control device 30 by querying the number of connections parameter of the CRCX command of the dominant protocol command stored in the first standby database 2100. In the exemplary embodiment, the number of connections parameter may be represented by different numbers or letters. In the exemplary embodiment, a number “0” represents that the first active card 230 is detecting the first terminal device 10, a number “1” represents that there is one connection between the first active card 230 and the media gateway control device 30, for example, the first terminal device 10 corresponding to the first active card 230 has established communication connection with the second terminal 50 via a CRCX command. A number “N” represents that there are N connections between the first active card 230 and the media gateway control device 30, for example, the first terminal device 10 corresponding to the first active card 230 has established communication connection with a plurality of second terminal devices 50 via a plurality of CRCX commands, each CRCX command corresponds to the first terminal device 10 establishing communication connection with each second terminal device 50.

When the first standby performing module 2101 determines that the number of connections is not 0, for example, the number of connections is N, in step S406, the first standby performing module 2001 generates a new CRCX command, and subtracts 1 from the number of connections after generating the new CRCX command. In the exemplary embodiment, the first standby performing module 2101 copies all parameters of CRCX command stored in the first standby database 2100 for generating the new CRCX command.

In step S408, the first performing module 2101 processes the new CRCX command. In the exemplary embodiment, the first performing module 2101 utilizes the new CRCX command as a CRCX command sent by the media gateway control device 30 for establishing connection with the media gateway control device 30.

When the first standby performing module 2101 determines that the number of connections is 0, in step S410, the first standby performing module 2101 generates a new RQNT command. In the exemplary embodiment, the first standby performing module 2101 copies all parameter of the RQNT command stored in the first standby database 2100 generating a new RQNT command.

In step S412, the first standby performing module 2101 processes the new RQNT command. In the exemplary embodiment, the first performing module 2101 utilizes the new RQNT command as a RQNT command sent by the media gateway control device 30 for detecting the status of the first terminal device 10, and sends the result of detecting to the media gateway control device 30.

In step S414, the first standby card 210 switches a standby state of the first standby card 210 into an active state for recovering the normal communication.

The first network device 20, 21 and the method for communication recovery reestablish the communication connection between the first terminal device 10 and the media gateway control device 30 when the active card is faulty, and thus increase communication reliability and stability.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A network device, comprising:
at least one active card for establishing telephony connection between a first terminal device and a second terminal device via a media gateway control device, and transmitting communication data between the first terminal device and the media gateway control device; and
a standby card for reestablishing telephony connection between the first terminal device and the second terminal device based on a redundancy command and a number of connections of the active card in response to a fault on the active card.

2. The network device of claim 1, wherein the active card further comprises:
a state module for recording a communication state between the first terminal device and the media gateway control device;
a database for storing the communication data between the first terminal device and the media gateway control device; and
a performing module for establishing the telephony connection between the first terminal device and the second terminal device utilizing the communication state recorded by the state module, and transmitting the communication data stored in the database.

3. The network device of claim 2, further comprising a processor for generating the redundancy command in response to the fault on the active card, the active card further sending the communication data to the processor, and the standby card further receiving and utilizing the redundancy command and the communication data sent by the processor for telephony connection reconstruction in response to the fault on the active card.

4. The network device of claim 3, wherein the standby card further comprises:
a standby database for storing the communication data sent by the processor;
a standby performing module for receiving the redundancy command, and reestablishing the telephony connection between the first terminal and the second terminal device based on the number of connections of the active card in response to the fault on the active card; and
a standby state module for recording the communication state between the first terminal device and the media gateway control device in response to the receiving of the redundancy command by the standby card.

5. The network device of claim 2, wherein the active card further sends the communication state to the standby card, and the standby card generates the redundancy command in response to the fault on the active card.

6. The network device of claim 5, wherein the standby card further comprises:
a standby database for storing the communication data sent by the active card;
a standby performing module for generating the redundancy command, and reestablishing the telephony connection between the first terminal device and the second terminal device based on the number of connections of the active card; and
a standby state module for recording the communication state between the first terminal device and the second terminal device in response to the redundancy command.

7. The network device of claim 1, wherein the communication data further comprise a plurality of dominant protocol commands, each dominant protocol command comprises a Create Connection command and a Notification Request command conforming to Media Gateway Control Protocol (MGCP), and the Create connection command comprises a number of connections parameter.

8. A method for communication recovery, used in a network device, comprising:
sending of communication data in a telephony connection between a first terminal device and a second terminal device by an active card;
receiving a redundancy command in response to a fault on the active card;
determining a number of connections of the active card via the communication data; and
reestablishing a telephony connection between the first terminal device and the second terminal device according to the number of connections in response to the redundancy command.

9. The method for communication recovery of claim 8, wherein the sending of the communication data further comprises:
sending of the communication data by the active card to a processor which sends the redundancy command.

10. The method for communication recovery of claim 9, wherein the receiving of the redundancy command further comprises:
receiving of the redundancy command sent by the processor by a standby card in response to the fault on the active card; and
receiving of the communication data sent by the processor by the standby card.

11. The method for communication recovery of claim 8, wherein the sending of the communication data further comprises:
sending of the communication data to a standby card by the active card in response to the fault on the active card.

12. The method for communication recovery of claim 11, wherein the receiving of the redundancy command further comprises:
receiving of the communication data sent by the active card by the standby card; and
generating of the redundancy command by the standby card in response to the fault on the active card.

13. The method for communication recovery of claim 8, wherein the communication data further comprises a plurality of dominant protocol commands, each dominant protocol command comprises a Create Connection command and a Notification Request command conforming to Media Gateway Control Protocol (MGCP), and the Create connection command comprises a number of connections parameter.

14. The method for communication recovery of claim 13, wherein the determining of the number of connections of the active card further comprises:
querying the number of connections parameter of the Create Connection command of the dominant protocol command stored in the standby card;
generating a new Create Connection command, and subtracting from the number of connections after generating the new Create Connection command if the number of connections is not 0; and
processing the new Create Connection command.

15. The method for communication recovery of claim 14, wherein the generating of the new Create Connection command comprises:
copying all parameters of the Create Connection command stored in the standby card for generating the new Create Connection command.

16. The method for communication recovery of claim 14, wherein the processing of the new Create Connection command further comprises:
utilizing the new Create Connection command as a Create Connection command sent by the media gateway control device to connect the first terminal device with the second terminal device.

17. The method for communication recovery of claim 13, wherein the determining of the number of connections of the active card further comprises:
generating a new Notification Request command if the number of connections is 0;
processing the new Notification Request command; and
switching a standby card from a standby state into an active state.

18. The method for communication recovery of claim 17, wherein the generating of the new Notification Request command further comprises:
copying all parameter of the Notification Request command stored in the standby card for generating the new Notification Request command.

19. The method for communication recovery of claim 17, wherein the processing of the new Notification Request command further comprises:
utilizing the new Notification Request command as a Notification Request command sent by the media gateway control device;
detecting a status of the first terminal device; and
sending a result of the detecting to the media gateway control device.

20. A network telephone gateway for establishing telephony communication connection between a first terminal and a second terminal device, the network telephone gateway comprising:
a plurality of active cards, each of which is capable of sending communication data between the first terminal and a media gateway control device;
a processor for detecting faults on the active cards and generating a redundancy command when detecting a fault on the active cards; and
a standby card for reestablishing telephony connection between the first terminal device and the second terminal device based on the redundancy command in response to the detected fault.
